(19) United States
(12) Patent Application Publication
(10) Pub. No.: US 2008/0274336 A1
(43) Pub. Date: Nov. 6, 2008

(54) High temperature insulation with enhanced abradability

(75) Inventors: Gary B. Merrill, Orlando, FL (US); Jay E. Lane, Mims, FL (US); Chris Campbell, Orlando, FL (US); Jay A. Morrison, Oviedo, FL (US)

Correspondence Address: Siemens Corporation;Intellectual Property Department, 170 Wood Avenue South, Iselin, NJ, 08830, US

(73) Assignee: Siemens Power Generation, Inc.

(21) Appl. No.: 11/607,344

(22) Filed: Dec. 1, 2006

(51) Int. Cl. B32B 3/02; B32B 5/16; B32B 3/30; B32B 3/28; B32B 3/00; C23C 14/30

(52) U.S. Cl. 428/168; 428/172; 428/313.3; 427/596

(57) ABSTRACT

A enhanced abradable friable graded insulator FGI results from the laser patterning of a coating where a series of top surfaces reside on a series of columns such that the walls of the columns are not significantly densified relative to the interior of the columns. Patterns can be generated where the columns are oriented independently normal to or at an acute angle to the top surfaces. The cross sections of the top surfaces are formed to conform to the average dimensions of the spheres of the FGI coating. The cross sections of the top surfaces can be more than 1.5 times the diameter of the spheres. Various patterns of top surfaces can be used including regular, random, quasiperiodic patterns. A gradient of abradability can be imposed on the coating.

### FIELD OF THE INVENTION

The invention relates to high temperature insulation for ceramic matrix composites and more particularly to an insulation coating with enhanced abradability.

### BACKGROUND OF THE INVENTION

Most components of combustion turbines require the use of a coating or insert to protect the underlying support materials and structure from the very high temperatures of the working environment. Coatings for ceramic matrix composite (CMC) structures have been developed to provide structures having high temperature stability of ceramics without the intrinsic brittleness and lack of reliability of monolithic ceramics. Although these coatings must resist erosion from the severe environment they are also required to preferentially wear or abrade as necessary. For example, the turbine ring seal must maintain a tight tolerance with the tips of the turbine blades. The surface of the ring seal must abrade when impacted by the blades to reduce damage to the blades and to maintain a tight tolerance.

A number of types of such CMC coatings have been developed. U.S. Pat. No. 6,641,907 teaches a coating that has come to be known as a friable graded insulation, (FGI), with temperature stability up to temperatures approaching 1700° C. U.S. Pat. No. 6,641,907 is incorporated by reference. Other known coating systems are less thermally stable, less capable of providing erosion resistance, and display an inferior thermal expansion match with the substrate, poorer bonding to the substrate, lower flexibility, and lower abradability at temperatures in the range of 1600° C.

It is desirable to have a coating where the abradability is up to three times greater than that inherent to the FGI coating. It is also desirable to maintain the erosion resistance and strength of the coating without sacrificing the overall useful life of the coating while substantially improving the abradability of the coating.

One method of increasing the abradability of an erosion resistant coating is to pattern the coating, leaving portions of the structure free of the coating material by controlling the mode of deposition of the ceramic coating. An early example of this is presented in U.S. Pat. No. 4,764,089. The patterning is formed by the generation of steps and grooves in an underlying metal structural material by a variety of techniques such as machining, electrodischarge machining, electrochemical machining, and laser machining. This is followed by the deposition of a uniformly thick metal bonding layer. An abradable ceramic layer is then plasma sprayed onto the upper surface of the bonding layer at a uniform rate and at a fixed angle to a reference plane of the surface at the base of the grooves. This provides a “line of sight” deposition with a pattern induced by the steps and grooves of the underlying structure, which results in formation of shadow gaps, composed of channels and regions of weak, relatively loosely consolidated ceramic material.

A more recent approach to producing a patterned ceramic coating by controlled deposition is presented in U.S. Pat. No. 6,887,528 where a profiled coating is deposited on an underlying smooth substrate surface by the use of a plasma spray of the coating through a mask or by the implementation of direct writing technology using a pen dispensing apparatus with a fluid slurry controlled by a computer. The deposited surface retains the initial void profile through a sintering process to fix the desired pattern with the desired channels.

Alternatives to depositing a coating with a pattern are to deposit a coating and then form the void profile by the removal of mass or by the molding of the coated portion of the turbine structure. U.S. Pat. No. 6,830,428 B2 describes the formation of channels by machining methods such as milling, drilling, electro-erosion, electrochemistry, chemical machining, laser machining, abrasive water jet machining, and ultrasound machining. The patterning method can also include the molding of a preform of powders that are to form the abradable material, using a mold having relief that is the inverse of the cells or channels. Particularly, the electro-erosion of a NiCrAl alloy containing hollow aluminum silicate beads was disclosed. The cells are formed with a depth greater than the maximum depth of abrasion, with cavity walls formed at an angle of 0 to 20 degrees relative to the general direction of the end portion of the blade expected to come into contact with the abradable pattern. The percent reduction in wear was approximately equal to the percentage of the percent void of the surface.

The removal of mass by the use of a laser as a method of patterning is the subject of U.S. Pat. No. 5,951,892. It is suggested that the specific pattern formed will depend upon the abradability improvement desired and that the depth of the removal should be the maximum depth of abrasion anticipated. The deposition of a NiCrAl bentonite layer by thermal spraying is disclosed, followed by the patterning of a diagonal transverse pattern of 45 degrees relative to the direction of the blade with lines separated by 0.050 inches and with a depth of 0.050 inches. Alternately, the laser drilling of holes indexed to 0.050 inches with an offset of 0.025 inches and drilled to a depth of 0.050 inches can be used.

Although the removal of mass would seem to inherently lead to a increase of abradability, properties contrary to the improvement of abradability have been demonstrated for ceramic materials when lasers are used to produce the features. U.S. Pat. No. 6,703,137 describes the laser cutting of a plurality of segmentation gaps where the laser cuts are limited to 50 microns and the cuts are U shape. The laser induces melting and subsequent resolidification of the ceramic to give a thicker layer at the generated wall surface. The resulting ceramic coating is disclosed to be optimal as a thermal barrier with strain tolerance.

U.S. Pat. No. 6,617,013 B2 discloses the use of a laser to form stitches in a CMC such that the material is melted under ablation by a laser where the ablated material is recast on the surfaces of the holes to form the stitches. Rather than resulting in the weakening of the composite, these laser formed stitches reinforce the interlaminar strength of the material and increase the through-thickness thermal conductivity.

The use of a laser to increase the abrasiveness of a ceramic coating is presented in U.S. Pat. No. 4,884,820. The enhanced cutting capability of the laser-engraved ceramic surface is attributed to the elevated areas acting as a collection of cutting edges and the depression areas around the elevated areas receiving the fine cutting debris during cutting.

### SUMMARY OF THE INVENTION

A coating comprises a friable graded insulation containing hollow ceramic spheres, where at least part of the coating is composed of isolated top surfaces on columns separated by channels that extend into but not through the thickness of the coating. The walls of the columns have essentially the same density as the interior of the column. The top surfaces can occupy 10 to 95 percent of the surface area. The top surfaces can be regular in shape and disposed in a periodic fashion over the scribed surface. The walls of the columns can be independently oriented normal to the surface to an angle of 45° to the surface. Additionally, the coating can have one or more sub-columns wherein the sub-columns support two or more columns.

The top surfaces can display a pattern that has two or more repeating shapes periodically, quasiperiodically, or randomly disposed on the surface. In one embodiment, the top surfaces have a minimum linear distance across the top surfaces of 1.5 times the average diameter of the spheres of the FGI. The height of all top surfaces can vary and can vary regularly or randomly over the coating. The coating can also contain a ceramic filler that resides in part or all of the channels wherein the abradability of the filler is higher than the insulation. These fillers can be selected from phosphates, silicates, zirconates or hafnates.

The invention is also directed to a method for producing an insulating coating with an enhanced abradable surface having the steps of: depositing a continuous layer of a friable graded insulation upon a substrate; ablating the continuous layer using a laser beam directed upon the surface of the layer at an angle and a beam focus for a prescribed time and speed to form channels surrounding a predetermined pattern of columns extending to predetermined depths with top surfaces at or below the original surface of the layer. The method can include a step of delivering a stream of a gas during ablation at a flow and pressure that can sweep ablated material away from the forming walls of the columns. The gas used can be inert and can be selected from a group consisting of argon, neon, helium, and nitrogen. The gas can be or include a reactive gas and can be selected from a group consisting of chlorine and hydrogen chloride. The method can have an additional step of ablating to a shorter depth such that sub-columns are formed which support two or more columns. The method can have an additional step of filling part or all of the channels surrounding the columns with a ceramic filler.

### BRIEF DESCRIPTION OF THE DRAWINGS

FIG. 1 is a pattern of square top surfaces disposed at a 30-degree angle to the path of an impinging element, indicated by an arrow, with one series of parallel channels normal to the surface and another series of parallel channels at an angle of 45 degrees to the surface.

FIG. 2 is a top view of a laser-scribed series of hexagons.

FIG. 3 is a top view of a laser-scribed series of Penrose darts and kites.

FIG. 4 is a top view of a laser scribed pattern of two squares superimposed over a closely packed layer of hollow spheres where the sides of the large squares are 1.5 times the outside diameter of the spheres and the sides of the small squares are the inside diameter of the spheres.

FIG. 5 is a pattern of pyramids where the width of the scribed channels are narrower as greater depths of the channel.

FIG. 6 is a pattern of squares where every other square has been ablated to give a regular series of columns where the top surfaces are at two different elevations.

FIG. 7 is a pattern of scribed channels resulting in pattern of squares top surfaces on columns where four columns with four top surfaces extend from a single sub-column.

FIG. 8 is a pattern of square top surfaces where the bottom half of the channel contain a ceramic filler material.

### DETAILED DESCRIPTION OF THE INVENTION

The present invention provides abradability enhancing features for friable graded insulation (FGI) coatings, primarily for use on ceramic matrix composite (CMC) components used in combustion turbines, to significantly improve the abradability of the coating. The surface of the coating is divided into columns with various shaped top surfaces. The columns extend a desired depth into the insulation or can extend to multiple depths to balance strength to abradability characteristics. The transition from the columns' wall surface to the top surface can have an abrupt transition from the surface of the wall of the column to the top surface with a clearly defined angle, but can also involve a curvature. Neither the surface of the walls or the columns nor the surface of the top surfaces need to be flat, although in many embodiments of the invention they are essentially flat. The columns do not extend through the entire depth of the coating, to avoid the exposure of the CMC substrate. It is preferred to limit the depth of the columns such that, upon maximum loss of surface by abrasion, scribed channels in the coating are avoided which otherwise could permit leakage of gases between the turbine blade and surface that is abraded. In order to optimize abradable wear and strength requirements, the depth of cuts may vary in the coating. For example, eighty percent of the cuts may have a depth of 0.5 mm while twenty percent of the cuts may have a depth of 1.0 mm.

The top surfaces can be shaped and aligned to present one or more edges at the top of the columns of this coating to the surface of an impinging element, such as a turbine blade such that the orientation of the edge promotes the abrasion of the column. The number of top surfaces, the width of channels between the columns, the angle of the walls relative to the top surfaces, the depth of the columns, and the shape of the top surfaces can be selected to optimize the overall properties of the coating and to balance the erosion resistance to the hot gas environment with the abradability. The features of the abradable coating can be varied to optimize the properties at different portions of the coating.

Laser ablation is a preferred method of preparing such columns as it permits the formation of very small features by the focusing of the laser. Laser ablation inherently results in a reinforced wall of the columns extending up to the top surfaces. This reinforcement consists of a dense coating material on the walls of columns formed during scribing of the channels, approaching the theoretical density maximum for the void free material of the coating, as compared to the density of the columns interior to the walls where voids are included by design or are inherent to the method of producing the coating. Such dense walls are inherently more erosion resistant, but are also less abradable. An important feature of the invention is to cut features with no or minimal densification of the walls formed upon scribing the features to achieve optimal abradability of the scribed material.

The present method includes the use of a laser beam accompanied by a high-pressure high-flow gas to dispel the molten ceramic as a plume away from the walls of the columns as they are being formed. In this manner the wall surface is relatively free of a resolidified dense ceramic layer. Typically the high-flow gas to be used is an inert gas, such as nitrogen, argon, neon, or helium. Alternately, or additionally, a reactive gas such as chlorine or hydrogen chloride can be used, or included in the gas, to chemically modify the structure of the ablation generated species to more volatile species that resist deposition on the walls of the columns. The use of such reactive gases require that conditions are maintained to avoid exposure of equipment and technicians to these gases.

The depth of the scribed channels depends upon the beam energy density, the laser pulse duration, and the laser wavelength. In general, deeper scribes are also wider scribes. However, the focus and homogeneity of the laser as well as the pattern and depth of ablation can be varied to change the width of the scribe and result in a slope to the column walls.

The propensity towards densification of the walls can be varied by the manner in which the laser is used to produce the channels. The use of a pulsed laser output beam source results in the densification of the wall if carried out without a means to avoid densification. Where desired, this can permit the reinforcement of the columns for some portion of the coating surface, for example at the edge of the area to be abraded. However, for the majority or all the coating surface to be ablated, the use of a pulsed laser with a high velocity gas stream can significantly reduce the degree of densification that occurs. As the invention is directed to the improvement of the abradability of a FGI coating, embodiments of the present invention are directed to the minimization of densification at the walls during laser scribing of channels.

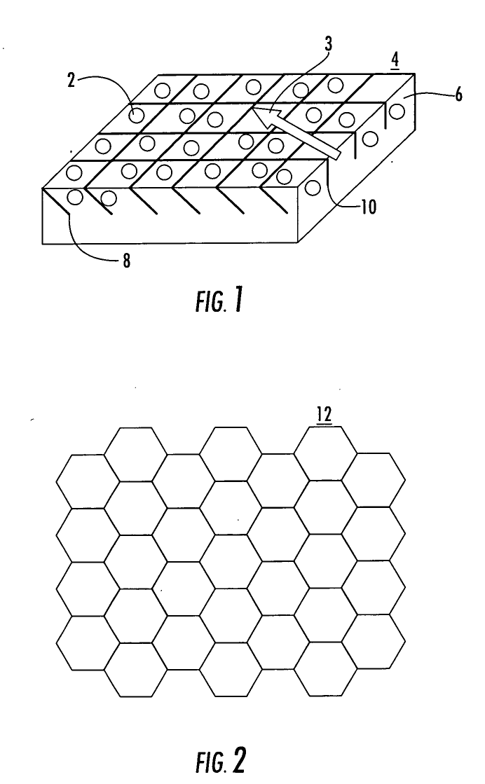

The angle of incidence of the laser beam can be varied to yield columns that are disposed at nearly any angle desired relative to the top surface, ranging from an acute angle to the top surface of the coating to normal to the top surface. The angle at which scribes are made can be changed to enhance the coating's abradability. The angle can be chosen with consideration given to the manner in which the abrading structure will impinge upon the abradable coating. Such a pattern is given in FIG. 1 where square top surfaces 4 to columns 6 are delineated by a series of parallel scribed channels 8 that are 45 degrees to the surface while the complimentary series of scribed channels 10 that forms the square top surfaces are normal to the surface. The path of the impinging element, such as a rotor blade, indicated in FIG. 1 by a bold arrow 3, is to be 30 degrees relative to one series of channels 10. Orientation to a channel of a top 4 at an angle of about 30 or about 60 degrees is advantageous for abrasion of the surface.

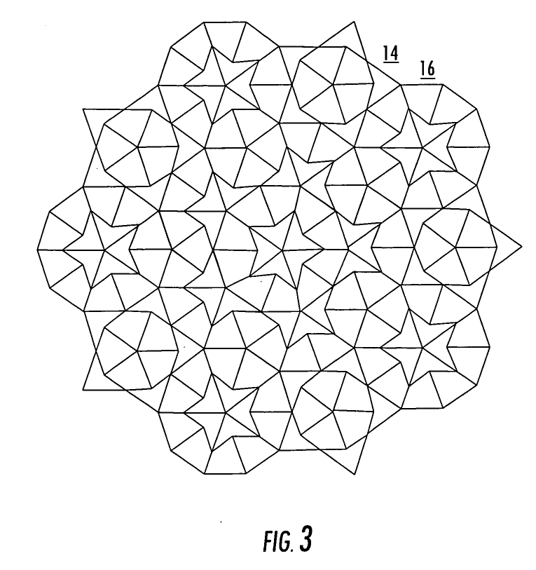

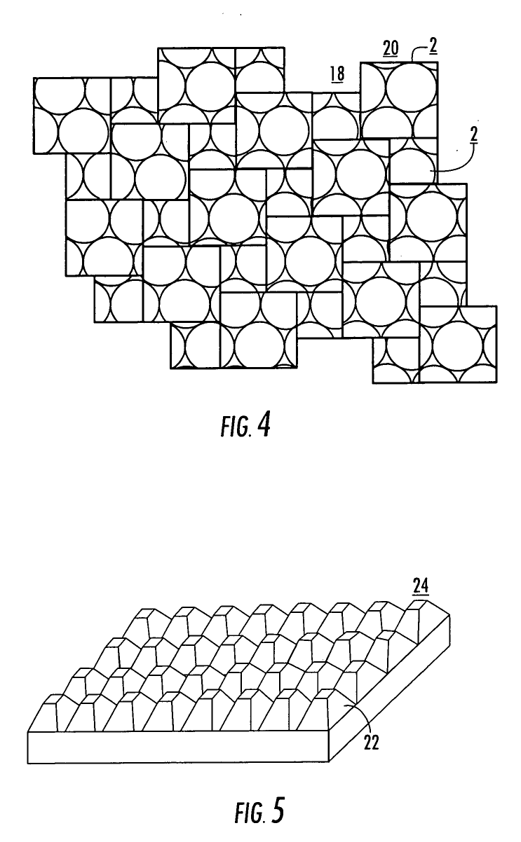

A wide variety of periodic shapes such as hexagons 12, shown in FIG. 2, and trapezoids where channels are not linearly continuous can be produced on the surface by intermittent laser scribing. In contrast, mechanical cutting of the surface only permits the formation of randomly shaped top surfaces and periodically shaped top surfaces such as triangles, squares, and rhombuses that result from continuous straight cuts. The laser can achieve periodic structure with two or more regular polygons, curved shapes, or even quasiperiodic structures, i.e. Penrose tiles, as shown in FIG. 3. Quasiperiodic patterns can result in relatively strong columns, with relatively large top surfaces, the kites 16 of FIG. 3, for example with a surface area of 3 or 4 mm², capable of accommodating entire spheres of an FGI, mixed with smaller relatively weak columns with relatively smaller top surfaces, the darts 14 of FIG. 3, for example with a surface area of 2.8 or 3.8 mm², where the shape and size is less capable of accommodating an entire sphere of an FGI. In like manner, periodic, as shown in FIG. 4, and random patterns can be formed where a mixture of relatively small weaker columns 18 and relatively large stronger columns 20 are formed on the same coating surface.

FIG. 4 gives a top pattern of a large square top surfaces 20 having an edge length of 1.5 D and a small square top surfaces 18 of edge length D-2w superimposed on a layer of an idealized hexagonal closest packed spheres 2 of diameter D. As can be seen in FIG. 4, most large square top surfaces 20 display a single complete sphere 2 in the area of the square. A typical FGI coating is composed of a random dispersion of hollow ceramic spheres that can be relatively monodispersed in size or can vary in size, for example from 1.0 to 1.5 m in diameter, with an average sphere diameter of D, in a ceramic matrix. To assure that the equivalent of a complete sphere can reside within the column, the minimal distance across a top surface of any given shape must have an effective length of at least 1.5 D and is preferably more than 2 D. Scribing that leads to a minimal distance across a top surface of less than 1.5 D results in an inherently weak column. Scribing to yield a minimal distance across a top of less than D minus two times the thickness of the sphere's walls, w, (i.e., the inside diameter of the hollow ceramic spheres), necessarily leads to the cleavage of some columns below the top surface when a single sphere was occupying the entire cross-section of the generated column. By scribing some or all columns with these dimensions, a series of columns results where the top surfaces are randomly disposed at different elevations as some spheres have been cleaved. Such a situation will lead to a gradient of abradability where the abradability decreases as the surface is progressively abraded.

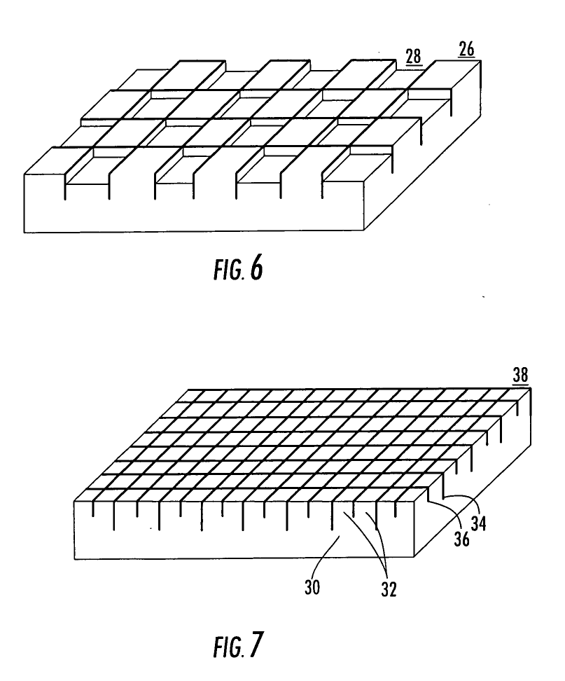

A gradient of abradability can be generated in a non-random fashion. This is illustrated in FIG. 5 where a series of columns that are square pyramids 22 with square top surfaces 24 are formed by the narrowing of the channel volume while increasing the depth of the channel. By increasing the focus of the laser, the width of the scribes can decrease with increasing depth. This increases the proportion of the cross-sectional area of the freshly exposed surface occupied by the FGI coating as the coating abrades, causing the abradability to decrease as the depth of abrasion increases. Separately or additionally, the elevation of the top surfaces can be varied by laser ablation to remove part of the coating from a top surface 26 to give an ablated top surface 28 or reduced elevation, as shown in FIG. 6 where every other top surface 28 of a pattern of squares is reduced in elevation. In this manner all top surfaces can have a minimal distance across the surface of at least 1.5 times the average diameter of the FGI spheres but the columns can have various heights by design leading to a gradient of abradability where the abradability decreases as the depth of the abrasion increases.

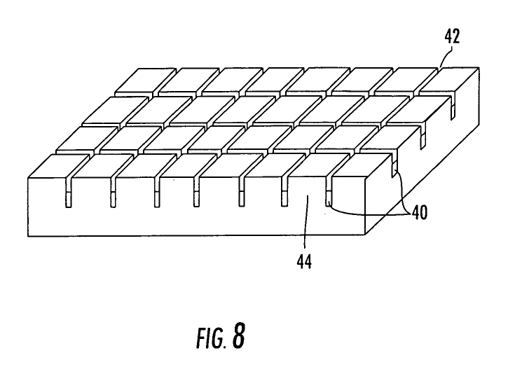

A gradient of abradability by design permits the manipulation of the initial or short-term abrasion characteristics of the coating and the ultimate or long-term abrasion characteristics. An alternate pattern to that described above with varying column heights is to generate the abradability gradient by successively dividing the columns into additional smaller columns as one proceeds from the base to the scribed coating layer to the surface. Another way to consider this structure is as a series of sub-columns 30 of a particular dimension that are additionally patterned by making multiple shallower scribes to yield two or more columns 32 that reside on the sub-columns. The manner and order by which the channels are scribed can be varied. For example, as shown in FIG. 7, a series of squares is defined by scribed channels 34 at a depth of 2× to form sub-columns 30 followed by forming channels 36 of depth X defining columns 32, at the middle of the parallel channels 34 defining the sub-columns 30. This leads to a structure of four relatively small square top surfaces 38 on columns 32 of depth X extending from larger square sub-columns 30. that extend an additional depth of X. In this form the columns 32 can be abraded from the coating during short-term wear, as in commissioning, leaving a surface with one fourth of the number of top surfaces, on the sub-columns, which are subsequently abraded during long-term wear. More than two levels of sub-columns of discontinuous depth can be achieved via the laser ablation method. Hence a gradient of abradability can be achieved as one proceeds from the top surface of the ceramic coating to the maximum abrasion depth. Such a gradient can provide very high abradability at a portion of the coating impinged upon during engine commissioning while providing more erosion resistance after the engine has been in service. Such staggering of channel depths also avoids planes of weakness in the abradable material. It is preferred to have multiple depths of scribes to avoid the alignment of the cuts, which can promote stress concentration.

As described above, the depth of the scribe can be controlled to a high tolerance to ensure the final tight seal between the insulator surface and the moving blade and avoid leakage of gases between the moving blade and the fixed surface after commissioning. To assure minimize leakage past the blade tips via the channels a filler ceramic material that has an inherently higher abradability than the FGI can be placed in the channels. This is shown in FIG. 8 where a filler ceramic material 40 occupies the bottom half of the scribed channels 42 around the columns 44. The filler ceramic material can have poorer erosion resistance to that of the FGI coating. A narrow aspect ratio of the channels 42 allows some shielding by the FGI columns of the filler ceramic material 40 from the erosive gases or gas-borne particles. Appropriate filler ceramic materials 40 include phosphates, silicates, zirconates and hafnates. Example compositions of these filler ceramic materials include monazite (yttrium phosphate), yttrium silicate, and gadolinium zirconate or gadolinium hafnate. Other examples of these and related oxides may include, but are not limited to: HfSiO₄, ZrSiO₄, Y₂O₃, ZrO₂, HfO₂, yttria and or rare earth partially or fully stabilized ZrO₂, yttria and/or rare earth partially or fully stabilized HfO₂, yttria and/or rare earth partially or fully stabilized ZrO₂/HfO₂, yttrium aluminum garnet (YAG); rare earth silicates of the form R₂Si₂O₇; oxides of the form R₂O₃; zirconates or hafnates of the form R₄Zr₃O₁₂ or R₄Hf₃O₂₃, where R may be one or more of Ce, Pr, Nd, Sm, Eu, Gd, Tb, Dy, Ho, Er, Tm, Yb, and Lu. The filler ceramic material are generally chosen based on the performance requirements of the filler in a given application. Preferably, the filler ceramic material 40 is filled to the complete depth of the channel to provide sealing in all areas including those where the blade tip rubs and those areas where the blade tip does not rub. Alternately, the filler ceramic material can be included to less than the complete depth of the columns, yielding an increasing gradient of sealing and a decreasing gradient of abradability. Different ceramic filler materials of various inherent erosion and abrasion resistance can be deposited at different depths of the FGI columns to achieve a desired abradability profile.

The alternatives for the coating and filling materials, patterns of top surfaces, angles of scribes to the top surfaces, depths of the channels relative to the coating, relative heights of top surfaces, the number and disposition of sub-channels, and gradient structure can be individually varied. Such variations will be apparent to those skilled in the art and do not limit the scope of the invention. Variations and modifications can be made without departing from the scope and spirit of the invention as defined by the following claims.

We claim:

1. A coating with an abradable surface, said coating comprising a friable graded insulation containing hollow ceramic spheres, wherein at least part of said coating is partitioned into isolated top surfaces on columns separated by channels that extend into but not through the thickness of said coating and wherein walls of said columns have essentially the same density as the interior of said column.

2. The coating of claim 1, wherein said top surfaces occupy 10 to 95 percent of said abradable surface.

3. The coating of claim 1, wherein said top surfaces are regular in shape and disposed in a periodic fashion.

4. The coating of claim 1, wherein the walls of said columns are independently oriented normal to said surfaces to an angle of about 45° to said surfaces.

5. The coating of claim 1, further comprising a plurality of sub-columns wherein each of said sub-columns support a plurality of said columns.

6. The coating of claim 1, wherein said top surfaces comprise a plurality of repeating shapes that are periodically, quasiperiodically, or randomly disposed.

7. The coating of claim 1, wherein said top surfaces have a minimum linear distance across said top surfaces of 1.5 times the average diameter of said spheres.

8. The coating of claim 1, wherein the height of all top surfaces vary regularly or randomly.

9. The coating of claim 1, further comprising a ceramic filler material residing in part or all of said channels wherein the abradability of said filler material is higher than said insulation.

10. The coating of claim 10, wherein the ceramic filler material comprises phosphates, silicates, zirconates, or hafnates.

11. A method for producing an insulating coating with an enhanced abradable surface comprising the steps of:
depositing a continuous layer of a friable graded insulation upon a substrate; and
ablating said continuous layer using a laser beam directed upon the surface of said layer at an angle and a beam focus for a prescribed time and speed to form a predetermined pattern of columns surrounded by channels extending to a predetermined depths.

12. The method of claim 11, further comprising the step of delivering a stream of a gas at the surface during ablation at a flow and pressure sufficient to sweep ablated material away from the forming walls of said columns.

13. The method of claim 12, wherein said gas is inert.

14. The method of claim 13 wherein said gas is selected from a group consisting of argon, neon, helium, and nitrogen.

15. The method of claim 12, wherein some or all of said gas is a reactive gas.

16. The method of claim 15 wherein said reactive gas is selected from a group consisting of chlorine and hydrogen chloride.

17. The method of claim 11, further comprising an additional step of ablating to a shorter depth such that sub-top surfaces on sub-columns are formed which support a plurality of columns.

18. The method of claim 12, further comprising the step of filling part or all of the channels surrounding said columns with a ceramic filler material.

19. The method of claim 18, wherein the ceramic filler material comprises phosphates, silicates, zirconates, and hafnates.
